(19) United States
(12) Patent Application Publication
(10) Pub. No.: US 2026/0104320 A1
(43) Pub. Date: Apr. 16, 2026

(54) TESTING A CONTROL DEVICE FOR AUTONOMOUS DRIVING

(71) Applicant: Ford Global Technologies, LLC, Dearborn, MI (US)

(72) Inventor: Turgay Isik Aslandere, Aachen/Nordrhein-Westfalen (DE)

(73) Assignee: Ford Global Technologies, LLC, Dearborn, MI (US)

(21) Appl. No.: 19/351,345

(22) Filed: Oct. 7, 2025

(30) Foreign Application Priority Data
Oct. 16, 2024 (DE) 102024129953.3

(51) Int. Cl. G01M 17/007; G06F 30/27; G06N 3/045

(52) U.S. Cl. CPC G01M 17/007; G06F 30/27; G06N 3/045

(57) ABSTRACT

A method for testing a control device which is configured to autonomously control a motor vehicle using environmental data that describes the environment of said motor vehicle, has the steps of: a) generating an environmental dataset simulating the environmental data, by inputting text describing a driving situation into a first neural network; b) inputting the environmental dataset into the control device, whereby the control device generates a control device output dataset, which comprises control data by means of which the control device is configured to control the motor vehicle, and state data describing a state of the motor vehicle; c) outputting the control device output dataset from the control device into a second neural network, which is different from the first neural network; d) outputting a network output dataset from the second neural network, wherein the network output dataset is generated using the control device output dataset; e) generating a further environmental dataset which simulates the environment and is different from at least a subset of the preceding environmental datasets, by means of the network output dataset and the first neural network; f) repeating steps b) to e) at least once.

### CROSS-REFERENCE TO RELATED APPLICATION

This patent application claims priority to German Application No. DE 102024129953.3, filed on Oct. 16, 2024, which is hereby incorporated by reference in its entirety.

### BACKGROUND

In the development of autonomously driven vehicles, tests can be performed. This can be carried out, for example, in the real world, by providing image data recorded by one or more cameras of the motor vehicle to a control device of the motor vehicle in real time and having the control device autonomously control the motor vehicle on the basis of the image data. To do this, it is necessary to equip a motor vehicle with the appropriate hardware, and it is also necessary to provide personnel to perform the test. This means that testing in the real world is inefficient. In another example, a virtual test can be performed by artificially generating image data, in a similar way to a computer game, using algorithms such as a renderer. However, developing such a renderer is also inefficient.

### SUMMARY

The present disclosure relates to a method for testing a control device for autonomous driving, and to a test device, a computer program and a storage medium for carrying out the method. The method for testing a control device for an autonomously driven motor vehicle is more efficient.

The method for testing a control device, which is configured to autonomously control the motor vehicle using environmental data describing an environment of a motor vehicle, comprises the steps of: a) generating an environmental dataset simulating the environmental data, by inputting text describing a driving situation into a first neural network; b) inputting the environmental dataset into the control device, whereby the control device generates a control device output dataset, which comprises control data by which the control device is configured to control the motor vehicle, and state data describing a state of the motor vehicle; c) outputting the control device output dataset from the control device into a second neural network, which is different from the first neural network; d) outputting a network output dataset from the second neural network, wherein the network output dataset is generated using the control device output dataset; e) generating a further environmental dataset which simulates the environment and is different from at least a subset of the preceding environmental datasets, by the network output dataset and the first neural network; f) repeating steps b) to e) at least once, wherein in step b) the further environmental data set generated in the final step e) is input into the control device.

For example, the text input in step a) can be performed by a person. Because the environmental dataset and the further environmental data set are generated by the first neural network, more realistic environmental data can be generated compared to when the environmental data is generated by an algorithm such as a renderer. A real-world test using a motor vehicle equipped with sensors to generate the realistic environmental data is not required. This makes the method simple to carry out. Since the second neural network outputs the network output dataset which is used to generate the further environmental data set, it is advantageously not necessary to describe a new driving situation by further text input by a person in order to carry out a further test, this being done automatically instead. The second neural network thus independently generates new driving situations, which allows the method to be carried out with particularly low complexity. The second neural network advantageously can be small. This has the advantage that it can be stored locally, such as on a personal computer, and does not need to be stored remotely, in a cloud, for example. This has the advantage that, for example, the data security can be increased. In addition, the data output of the second neural network requires only low bandwidth. In particular, the second neural network creates driving situations that become increasingly difficult.

The second neural network can be a smaller version of the first neural network. It is possible that the second neural network will be trained by fine tuning. This means that the first layer of the neural network is not changed, but only the layers of the second neural network that follow the first layer.

It is possible that, in the event that the state data indicates that the control device has committed a driving error, the method is terminated.

It is possible that, in the event that the state data indicate that the control device has committed a driving error, an error message is output. It is possible that the error message includes displaying the particular environmental data which caused the driving error. This allows an error analysis to be performed.

It is possible that in step a) a text encoder output dataset is generated from the text input by a text encoder, and the output dataset is input into the first neural network. The text encoder can thus use the text input, which is readable and can be formulated by a human being, to generate a sequence of numbers as the text encoder output dataset, wherein the sequence of numbers serves as the input into the first neural network.

The text encoder can be a large language model or can comprise a large language model. The large language model is referred to as an LLM. It is possible that the first neural network comprises or is a conditional generative adversarial network. The conditional generative adversarial network is referred to as a cGAN. It is possible that the second neural network comprises or is a large language model. It is possible that the second neural network has a transformer architecture. The transformer architecture is referred to as the transformer architecture.

The environmental data preferably contains image data. Alternatively or in addition, the environmental data contains radar data and/or lidar data.

It is possible that the environmental dataset simulates the environmental data for only a single time point and the further environmental dataset simulates the environmental data for only a single time point. Alternatively, it is possible that the environmental dataset simulates the environmental data for multiple consecutive time points and the further environmental dataset simulates the environmental data for multiple consecutive time points.

The test device according to the disclosure is configured to carry out the method. The test device may comprise a storage medium and/or a processor for this purpose. In addition, the test device may comprise the control device.

The computer program according to the disclosure comprises commands, which during the execution of the computer program by a computer cause said computer to carry out the method.

The computer-readable storage medium comprises commands, which during the execution of the computer program by a computer cause said computer to carry out the method.

### BRIEF SUMMARY OF THE DRAWINGS

The present invention is explained in more detail with the aid of the accompanying schematic drawings. In the drawing:

FIG. 1 shows a diagram illustrating the data flows and

FIG. 2 shows a diagram illustrating the steps carried out in the method.

### DESCRIPTION

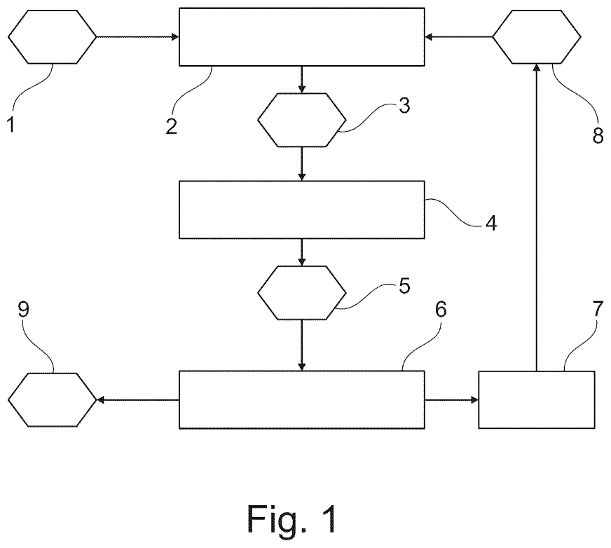

FIG. 1 illustrates a method for testing a control device 6 which is configured to autonomously control a motor vehicle using environmental data 5 that describes the environment of said motor vehicle. The control device can comprise a device processor and/or a device storage medium for autonomously controlling the motor vehicle based on the environmental data. A model and/or a piece of software to be tested may be stored on the device storage medium. In addition or alternatively, the hardware of the control device 6, including the device processor and/or the device storage medium, can be tested.

The environmental data 5 can include, for example, image data, such as image data recorded by a camera or by multiple cameras, radar data and/or lidar data.

The method comprises step a): generating an environmental dataset simulating the environmental data 5, by inputting text 1 describing a driving situation into a first neural network 4. For example, the text input 1 can be performed by a person. The text input can comprise words and/or entire sentences. This means the driving situation can be described. For example, information may be provided about lighting conditions (such as day or night), weather conditions (such as cloudy, not cloudy, rain and/or snow), traffic conditions (no other traffic, a large amount of other traffic, parked cars, no parked cars), and/or road type (such as roads in a city, rural road, motorway). The first neural network 4 may, for example, comprise or be a conditional generative adversarial network.

It is possible that in step a) a text encoder output dataset 3 is generated from the text input 1 by a text encoder 2, and the output dataset is input into the first neural network 4, in particular input directly into the first neural network 4. For example, the text encoder 2 can comprise or be a large language model.

The method comprises step b): inputting the environmental dataset into the control device 6, whereby the control device 6 generates a control device output dataset, which comprises control data by which the control device 6 is configured to control the motor vehicle, and state data describing a state of the motor vehicle. The control data may include, for example, a steering angle, a position of an accelerator pedal, a gear, and/or a position of a brake pedal. The state data may include, for example, a speed of the motor vehicle, a direction of movement of the motor vehicle and/or information on whether a driving error has been committed and/or whether the driving situation has been properly mastered.

The method comprises step c): outputting the control device output dataset from the control device 6 into a second neural network 7, which is different from the first neural network 4, wherein the second neural network 7 is completely separated from the first neural network 4. The second neural network 7 may, for example, comprise or be a large language model. The second neural network 7 may have a transformer architecture.

The method comprises step d): outputting a network output dataset 8 from the second neural network 7, wherein the network output dataset 8 is generated using the control device output dataset. It is possible that the network output dataset 8 consists of a sequence of numbers and is not in text form. It is possible that the network output dataset 8 is input directly into the text encoder 2. It is possible that the text input 1 is passed through neural layers of the text encoder 2 through which the network output dataset 8 is not passed. As an alternative to inputting the network output dataset 8 directly into the text encoder 2, the network output dataset 8 can also be input directly into the first neural network 4.

The method comprises step e): generating a further environmental dataset which simulates the environment 5 and is different from at least a subset of the preceding environmental datasets, by the network output dataset 8 and the first neural network 4.

The method comprises step f): repeating steps b) to e) at least once, e.g., multiple times, wherein in step b) the further environmental data set generated in the final step e) is input into the control device (6).

The first neural network 4 is configured to simulate the environmental data 5, whereas the second neural network 7 is configured to interpret the control device output dataset based on the state data contained therein, and from this to generate the network output data set 8, by which the first neural network 4 generates the further environmental data set.

In the event that the state data indicate that the control device 6 has committed a driving error, the method can be terminated. In the event that the control device 6 has committed the driving error, an error message 9 can be output. The error message 9 can include displaying the particular environmental data 5 which caused the driving error.

It is possible that the environmental dataset simulates the environmental data 5 for only a single time point and the further environmental dataset simulates the environmental data 5 for only a single time point. Alternatively, it is possible that the environmental dataset simulates the environmental data 5 for multiple consecutive time points and the further environmental dataset simulates the environmental data 5 for multiple consecutive time points.

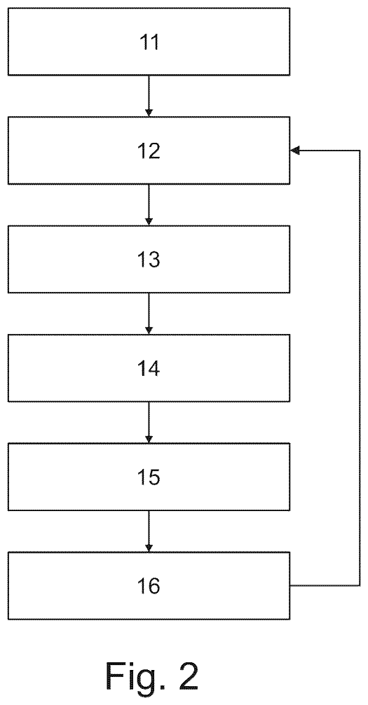

In FIG. 2, the method is illustrated with the steps 11 to 16. In a step 11, the text input 1 takes place, in which a person can describe the driving situation. In a step 12, the text input 1 is input into the text encoder 2 and the text encoder 2 outputs the text encoder output dataset 3. The text encoder output dataset 3 is input into the first neural network 4 in a step 13 and the neural network 4 outputs the environmental data 5 in the form of the environmental dataset or the further environmental dataset. In a step 14, the environmental data 5 is input into the control device 6 and the control device 6 outputs the control device output dataset. In a step 15, the control device output dataset is input into the second neural network 7 and the second neural network 7 outputs the network output dataset 8. In a step 18, the network output dataset 8 is supplied to the text encoder, whereby the method continues with step 12.

### LIST OF REFERENCE SIGNS

1 text input
2 text encoder
3 text encoder output dataset
4 first neural network
5 environmental data
6 control device
7 second neural network
8 network output dataset
9 error message
11 step
12 step
13 step
14 step
15 step
16 step

1.-16. (canceled)

17. A method for testing a control device which is configured to autonomously control a motor vehicle using environmental data that describes the environment of said motor vehicle, the method comprising steps of:
a) generating an environmental dataset simulating the environmental data, by inputting text describing a driving situation into a first neural network;
b) inputting the environmental dataset into the control device, wherein the control device generates a control device output dataset, which comprises control data by which the control device is configured to control the motor vehicle, and state data describing a state of the motor vehicle;
c) outputting the control device output dataset from the control device into a second neural network, which is different from the first neural network;
d) outputting a network output dataset from the second neural network, wherein the network output dataset is generated using the control device output dataset;
e) generating a further environmental dataset which simulates the environment and is different from at least a subset of the preceding environmental datasets, by the network output dataset and the first neural network;
f) repeating steps b) to e) at least once, wherein in step b) the further environmental data set generated in the final step e) is input into the control device.

18. The method of claim 17, wherein in the event that the state data indicates that the control device has committed a driving error, the method is terminated and/or an error message is output.

19. The method of claim 18, wherein the error message includes displaying environmental data which caused the driving error.

20. The method of claim 17, wherein in step a) a first text encoder output dataset is generated from the text input by a text encoder, and said output dataset is input into the first neural network.

21. The method of claim 20, wherein the text encoder comprises or is a large language model.

22. The method of claim 17, wherein the first neural network comprises or is a conditional generative adversarial network.

23. The method of claim 22, wherein the second neural network has a transformer architecture and/or comprises a large language model.

24. The method of claim 17, wherein the environmental data comprises image data, radar data and/or lidar data.

25. The method of claim 17, wherein the environmental dataset simulates the environmental data for only a single time point and the further environmental dataset simulates the environmental data for only a single time point.

26. The method of claim 17, wherein the environmental dataset simulates the environmental data for multiple consecutive time points and the further environmental dataset simulates the environmental data for multiple consecutive time points.

27. A test device, which is configured to test a control device which is configured to autonomously control a motor vehicle using environmental data that describes the environment of said motor vehicle, including by:
a) generating an environmental dataset simulating the environmental data, by inputting text describing a driving situation into a first neural network;
b) inputting the environmental dataset into the control device, wherein the control device generates a control device output dataset, which comprises control data by which the control device is configured to control the motor vehicle, and state data describing a state of the motor vehicle;
c) outputting the control device output dataset from the control device into a second neural network, which is different from the first neural network;
d) outputting a network output dataset from the second neural network, wherein the network output dataset is generated using the control device output dataset;
e) generating a further environmental dataset which simulates the environment and is different from at least a subset of the preceding environmental datasets, by the network output dataset and the first neural network;
f) repeating steps b) to e) at least once, wherein in step b) the further environmental data set generated in the final step e) is input into the control device.

28. The method of claim 27, wherein in the event that the state data indicates that the control device has committed a driving error, the method is terminated and/or an error message is output.

29. The method of claim 28, wherein the error message includes displaying environmental data which caused the driving error.

30. The method of claim 27, wherein in step a) a first text encoder output dataset is generated from the text input by a text encoder, and said output dataset is input into the first neural network.

31. The method of claim 30, wherein the text encoder comprises or is a large language model.

32. The method of claim 27, wherein the first neural network comprises or is a conditional generative adversarial network.

33. The method of claim 32, wherein the second neural network has a transformer architecture and/or comprises a large language model.

34. The method of claim 27, wherein the environmental data comprises image data, radar data and/or lidar data.

35. The method of claim 27, wherein the environmental dataset simulates the environmental data for only a single time point and the further environmental dataset simulates the environmental data for only a single time point.

36. The method of claim 27, wherein the environmental dataset simulates the environmental data for multiple consecutive time points and the further environmental dataset simulates the environmental data for multiple consecutive time points.
